(19) United States
(12) Patent Application Publication
(10) Pub. No.: US 2011/0156729 A1
(43) Pub. Date: Jun. 30, 2011

(54) TEST APPARATUS AND TEST METHOD

(75) Inventor: Kenji TAMURA, Gunma (JP)

(73) Assignee: ADVANTEST CORPORATION, Tokyo (JP)

(21) Appl. No.: 12/984,546

(22) Filed: Jan. 4, 2011

Related U.S. Application Data
(63) Continuation of application No. PCT/JP2009/003210, filed on Jul. 9, 2009.

(30) Foreign Application Priority Data
Jul. 9, 2008 (JP) 2008-179166

(51) Int. Cl. G01R 31/00

(52) U.S. Cl. 324/750.01

(57) ABSTRACT

A test apparatus and a test method with which a circuit size can be decreased are provided. A recovered clock generating circuit generates a recovered clock of which phase is approximately the same as a phase of output data output by a device under test (DUT). The recovered clock generating circuit includes a phase comparator that compares a phase of the output data of the DUT to a phase of the recovered clock to generate a phase difference signal, a binary counter of which output value is incremented or decremented based on the phase difference signal, a control signal generating section that generates a control signal based on an output value of the binary counter, and a phase shifter that shifts the phase of the reference clock based on the control signal.

### BACKGROUND

1. Technical Field

The present invention relates to a test apparatus and a test method. The present invention relates to in particular a test apparatus and a test method with which a circuit size can be reduced.

2. Related Art

Japanese patent application publication 2005-285160 is an example of related art. In a test apparatus of the example, clock recovery is performed using a phase-locked loop (PLL) in order to allow a recovered clock signal to follow a timing variation in output data of a device under test, and thereby the recovered clock and the output data is synchronized.

Inventors of the present application have invented a test apparatus in which the output data is synchronized with the recovered clock using an IQ modulator instead of a PLL. By using an IQ modulator, it is possible to obtain various advantageous effects such as a small loop latency and an increased time margin at a timing comparator.

However, when the IQ modulator is used, a scale of a circuit that generates amplitude control signals based on comparison results between the recovered clock and the output data to supply the signals to an I side and a Q side of the IQ modulator becomes relatively large.

### SUMMARY

Therefore, it is an object of an aspect of the innovations herein to provide a test apparatus and a test method, which are capable of overcoming the above drawback accompanying the related art. The above and other objects can be achieved by combinations described in the claims. A first aspect of the innovations may include a test apparatus that tests a device under test. The test apparatus includes a reference clock source that generates a reference clock for controlling operations of the device under test, a recovered clock generating circuit that generates a recovered clock having approximately the same phase as a phase of output data output by the device under test, a data acquiring section that acquires an output value of the output data at a timing indicated by a strobe signal that is based on the recovered clock, a comparator that compares the output value acquired by the data acquiring section to a prescribed expected value, and a judging section that judges pass or fail of the device under test based on a comparison result made by the comparator. The recovered clock generating circuit includes a phase comparator that compares the phase of the output data output by the device under test to the phase of the recovered clock, and that outputs a phase difference signal, a binary counter that increments or decrements an output value based on the phase difference signal, a control signal generating section that generates a control signal based on the output value of the binary counter; and a phase shifter that shifts the phase of the reference clock based on the control signal.

In the test apparatus, the phase shifter may be an IQ modulator that has an I input and a Q input, the control signal generating section may include an I-side control signal selecting circuit that supplies an amplitude control signal to the I input and a Q-side control signal selecting circuit that supplies an amplitude control signal to the Q input. One of the I-side control signal selecting circuit and the Q-side control signal selecting circuit is selected in accordance with an upper bit of the output value of the binary counter, an amplitude control signal based on a lower bit of the output value of the binary counter may be output by the selected one of the I-side control signal selecting circuit and the Q-side control signal selecting circuit, and a fixed value may be output by the other of the I-side control signal selecting circuit and the Q-side control signal selecting circuit.

The I-side control signal selecting circuit and the Q-side control signal selecting circuit may be multiplexers that select one of multiple inputs based on an upper bit of the binary counter, and a lower bit of the binary counter, an inverted bit of the lower bit, a bit sequence indicating a maximum value and a bit sequence indicating a minimum value may be input to the multiplexers. The phase shifter may further include a low-pass filter that removes a high-frequency wave included in the output of the IQ modulator. The phase shifter may further include a frequency divider that divides a frequency of the output from the IQ modulator. A frequency divider that divides a frequency of the recovered clock output by the recovered clock generating circuit may be further provided, and the data acquiring section may acquire the output value of the output data at a timing indicated by a strobe signal that is based on the recovered clock of which frequency is divided by the frequency divider.

A second aspect of the innovations may include a test method for testing a device under test. The method includes generating a reference clock for controlling operations of the device under test, generating a recovered clock that has approximately the same phase as a phase of output data output by the device under test, acquiring an output value of the output data at a timing indicated by a strobe signal that is based on the recovered clock, comparing the acquired output value to a prescribed expected value; and

judging pass or fail of the device under test based on a comparison result made in the comparing. The generating the recovered clock includes

comparing the phase of the output data output by the device under test to the phase of the recovered clock to output a phase difference signal, incrementing or decrementing an output value of a binary counter based on the phase difference signal, generating a control signal based on the output value of the binary counter; and shifting the phase of the reference clock based on the control signal.

The shifting the phase is IQ modulation that has an I input and a Q input, the generating the control signal includes selecting an I-side control signal to supply an amplitude control signal to the I input and selecting a Q-side control signal to supply an amplitude control signal to the Q input. One of the selecting the I-side control signal and the selecting the Q-side control signal may be selected in accordance with an upper bit of the output value of the binary counter, an amplitude control signal based on a lower bit of the output value of the binary counter may be output in the selected one of the selecting the I-side control signal and the selecting the Q-side control signal, and a fixed value may be output in the other of the selecting the I-side control signal and the selecting the Q-side control signal.

The selecting the I-side control signal and the selecting the Q-side control signal are multiplexing in which one of multiple inputs is selected based on an upper bit of the binary counter, and a lower bit of the binary counter, an inverted bit of the lower bit, a bit sequence indicating a maximum value and a bit sequence indicating a minimum value may be input in the multiplexing. The shifting the phase may further includes low-pass filtering an output of the IQ modulation to remove a high-frequency wave included therein. The shifting the phase may further includes dividing a frequency of an output of the IQ modulation. The method further includes dividing a frequency of the generated recovered clock, and in the acquiring the output value of the output data, the output value of the output data may be acquired at a timing indicated by a strobe signal that is based on the recovered clock of which frequency is divided in the dividing.

The present invention may be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 illustrates a configuration example of a test apparatus 100 according to an embodiment of the invention.

FIG. 2 illustrates a table of truth value for an I-side control signal selecting circuit 121 and a Q-side control signal selecting circuit 122.

FIG. 3 illustrates an example of trajectories drawn by an I signal and a Q signal which are orthogonal to each other.

FIG. 4 illustrates an exemplary relation between the output value and trajectories of the amplitudes of the I signal and the Q signal which are orthogonal to each other.

FIG. 5 illustrates an example of relations between bit values output by four-input multiplexers 141 and 143 and analog values output by D/A converters 142 and 144 based on the bit values output by the multiplexers.

FIG. 6 illustrates amplitudes that correspond to the bit values output by the four-input multiplexers as the trajectories of the I signal and the Q signal that are orthogonal to each other.

FIG. 7 illustrates relations between states and the upper 2 bits of output value output by a binary counter 112.

FIG. 8 illustrates an example of relations among the state and the output values output by the four-input multiplexers 141 and 143, depending on the output value output by the binary counter 112.

FIG. 9 is a block diagram of the test apparatus 100 in which a frequency divider is provided in the phase shifter 114.

### DESCRIPTION OF EXEMPLARY EMBODIMENTS

Hereinafter, an embodiment of the present invention will be described. The embodiment does not limit the invention according to the claims, and all the combinations of the features described in the embodiment are not necessarily essential to means provided by aspects of the invention.

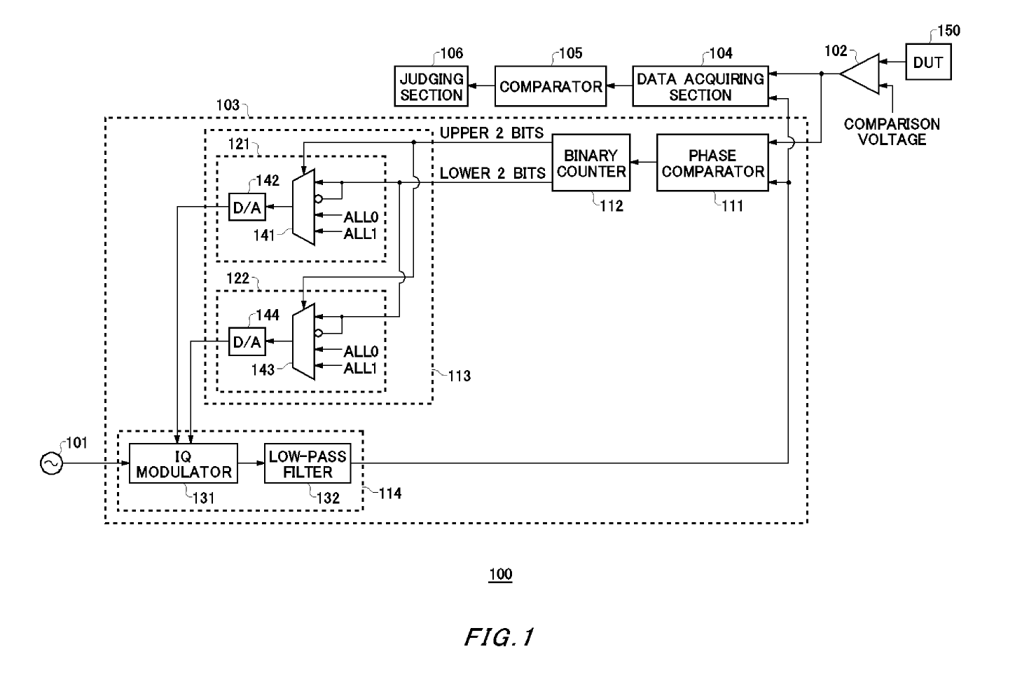

FIG. 1 illustrates a configuration example of a test apparatus 100 according to an embodiment. The test apparatus 100 includes a reference clock source 101, a level comparator 102, a recovered clock generating circuit 103, a data acquiring section 104, a comparator 105 and a judging section 106.

The reference clock source 101 generates an alternating current signal. The alternating current signal generated by the reference clock source 101 is referred to as a reference clock. A frequency of the reference clock is referred to as a reference frequency. The reference clock source 101 outputs the generated reference clock to a hereunder described IQ modulator 131 in the recovered clock generating circuit 103.

The reference clock generated by the reference clock source 101 is used to control operations of a device under test or DUT 150. In other words, the reference clock source 101 generates the reference clock for controlling operations of the DUT 150. The DUT 150 operates based on the reference clock generated by the reference clock source 101 and outputs output data.

The level comparator 102 compares the output data output by the DUT 150 to a prescribed comparison voltage, and generates binary output data. The level comparator 102 supplies the generated output data to the hereunder described recovered clock generating circuit 103 and the data acquiring section 104.

The recovered clock generating circuit 103 generates, based on the reference clock from the reference clock source 101, a recovered clock of which frequency is approximately the same as the reference frequency of the reference clock and of which phase is approximately the same as a phase of the output data. The recovered clock generating circuit 103 then outputs the generated recovered clock to the data acquiring section 104.

The data acquiring section 104 acquires an output value of the output data from the DUT 150 at a timing indicated by a strobe signal based on the received recovered clock. The data acquiring section 104 then outputs the obtained output value to the comparator 105. The data acquiring section 104 may be a timing comparator.

The strobe signal based on the recovered clock may be a signal that is generated by delaying the phase of the recovered clock. Alternatively, the strobe signal may be the recovered clock as it is. When the strobe signal is the recovered clock of which phase is delayed, a delaying circuit may be provided in the data acquiring section 104, and the delaying circuit may generate the strobe signal from the recovered clock. Alternatively, a delaying circuit may be provided between the data acquiring section 104 and the recovered clock generating circuit 103, this delaying circuit may generate the strobe signal from the recovered clock that is output by the recovered clock generating circuit 103, and then may supply the generated strobe signal to the data acquiring section 104.

The comparator 105 compares the output value sent from the data acquiring section 104 to a prescribed expected value, and outputs fail data or pass data to the judging section 106. The judging section 106 judges pass or fail of the DUT 150 based on the comparison result made by the comparator 105. The comparator 105 may acquire the expected value from the outside and may compare the output value to the acquired expected value.

The recovered clock generating circuit 103 will be now described. The recovered clock generating circuit 103 includes a phase comparator 111, a binary counter 112, a control signal generating section 113 and a phase shifter 114. A signal output by the phase shifter 114 in the recovered clock generating circuit 103 is referred to as a recovered clock. The phase shifter 114 includes an IQ modulator 131 which has an I input and a Q input, and a low-pass filter 132.

Output data output by the level comparator 102 and the recovered clock output by the phase shifter 114 are supplied to the phase comparator 111. The phase comparator 111 compares the phase of the output data supplied thereto with the phase of the recovered clock to generate a phase difference signal. The phase comparator 111 then outputs the generated phase difference signal to the binary counter 112.

The binary counter 112 increments or decrements a counter value based on the phase difference signal supplied from the phase comparator 111, and then outputs the resulting counter value. Here, the binary counter 112 is a 4-bit binary counter. The binary counter 112 supplies a 4-bit output value to the control signal generating section 113. The binary counter 112 outputs one of “0000,” “0001,” “0010,” “0011,” “0100,” “0101,” “0110,” “0111,” “1000,” “1001,” “1010,” “1011,” “1100,” “1101,” “1110” and “1111,” as an output value.

The control signal generating section 113 generates a control signal based on an output value output by the binary counter 112. The generated control signal is a control signal with which the output data is synchronized with the recovered clock. The control signal generating section 113 supplies the generated control signal to the IQ modulator 131 in the phase shifter 114. The control signal generating section 113 generates an I-input amplitude control signal and a Q-input amplitude control signal as control signals. The control signal generating section 113 supplies the generated I-input amplitude control signal and the Q input amplitude control signal to the I input and the Q input of the IQ modulator 131 respectively.

The IQ modulator 131 is supplied with the reference clock output by the reference clock source 101 and the control signal output by the control signal generating section 113. The IQ modulator 131 generates a signal by shifting the phase of the reference clock by a prescribed angle based on the control signal supplied from the control signal generating section 113. The IQ modulator 131 outputs the generated signal to the low-pass filter 132.

More specifically, the IQ modulator includes a phase shifter, a first multiplier, a second multiplier and an adder though these are not shown in the drawing. The phase shifter in the IQ modulator shifts a phase of the reference clock by 90°. The first multiplier has the I input. The second multiplier has the Q input.

The first multiplier multiplies the reference clock by an amplitude control signal supplied thereto from the I input, and outputs the multiplied result. The second multiplier multiplies the reference clock of which phase is shifted by 90° by an amplitude control signal supplied thereto from the Q input, and outputs the multiplied result. The adder adds the signal output by the first multiplier to the signal output by the second multiplier. A phase of a signal output by the adder is shifted with respect to the phase of the reference clock by a prescribed angle. In this way, a phase shifting angle can be changed depending on the amplitude control signal supplied to the I input and the amplitude control signal supplied to the Q input. A phase of the signal output by the IQ modulator 131 is referred to as an output phase.

The low-pass filter 132 removes a high-frequency component from the signal supplied thereto by the IQ modulator 131, and outputs the resulting signal. The low-pass filter 132 may be a low-pass filter of which cutoff frequency is several GHz or higher. A signal output from the low-pass filter 132 is supplied to the data acquiring section 104 and the phase comparator 111 as the recovered clock.

As described above, the phase comparator 111 compares a phase of the output data of the DUT 150 to a phase of the recovered clock, and outputs a phase difference signal to the binary counter 112. The binary counter 112 increments or decrements a value based on the phase difference signal, and then outputs the incremented or decremented value as an output value to the control signal generating section 113. The control signal generating section 113 generates, based on the supplied output value, a control signal with which a phase of the output data is synchronized with a phase of the recovered clock. In this way, the phase shifter 114 can generate a recovered clock of which phase is synchronized with a phase of the output data.

Next, the control signal generating section 113 will be described in detail. The control signal generating section 113 includes an I-side control signal selecting circuit 121 and a Q-side control signal selecting circuit 122. The output value output by the binary counter 112 is supplied to the I-side control signal selecting circuit 121 and the Q-side control signal selecting circuit 122. The I-side control signal selecting circuit 121 generates, based on the supplied output value, an amplitude control signal that is supplied to the I input of the IQ modulator 131. The Q-side control signal selecting circuit 122 generates, based on the supplied output value, an amplitude control signal that is supplied to the Q input of the IQ modulator 131.

At this point, depending on a state represented by upper 2 bits of the output value output by the binary counter 112, one of the I-side control signal selecting circuit 121 and the Q-side control signal selecting circuit 122 is selected. From the selected one of the I-side control signal selecting circuit 121 and the Q-side control signal selecting circuit 122, an amplitude control signal that is based on lower 2 bits of the output value output by the binary counter 112 is supplied to the IQ modulator 131. From the other of the I-side control signal selecting circuit 121 and the Q-side control signal selecting circuit 122, which is not selected, a fixed value is supplied to the IQ modulator 131.

In other words, when the I-side control signal selecting circuit 121 outputs the amplitude control signal that is based on the lower 2 bits of the output value, the Q-side control signal selecting circuit 122 outputs a fixed value. When the Q-side control signal selecting circuit 122 outputs the amplitude control signal that is based on the lower 2 bits of the output value, the I-side control signal selecting circuit 121 outputs a fixed value.

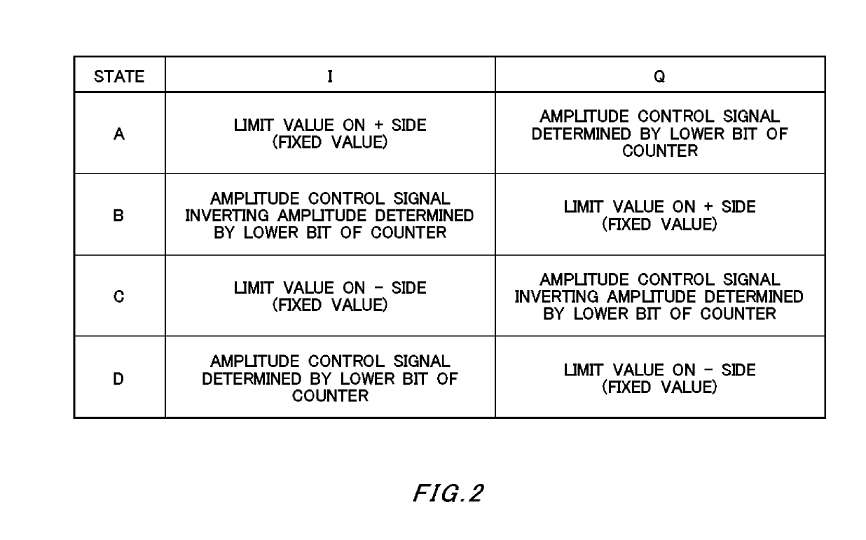

FIG. 2 illustrates a table of truth value for the I-side control signal selecting circuit 121 and the Q-side control signal selecting circuit 122. In a state A, an amplitude control signal output by the I-side control signal selecting circuit 121 is a limit value on a +side, which is a fixed value, and an amplitude control signal output by the Q-side control signal selecting circuit 122 is an amplitude control signal that is determined by the lower 2 bits of the output value output by the binary counter 112.

In other words, in the state A, the Q-side control signal selecting circuit 122 is selected, and the Q-side control signal selecting circuit 122 outputs the amplitude control signal that is based on the lower 2 bits of the output value of the binary counter 112. At the same time, the I-side control signal selecting circuit 121, which is not selected, outputs a fixed value.

In a state B, an amplitude control signal output by the I-side control signal selecting circuit 121 is an amplitude control signal that inverts the amplitude determined by the lower 2 bits of the output value of the binary counter 112, and an amplitude control signal output by the Q-side control signal selecting circuit 122 is the limit value on the +side, which is a fixed value.

In other words, in the sate B, the I-side control signal selecting circuit 121 is selected, and the I-side control signal selecting circuit 121 outputs the amplitude control signal that is based on the lower 2 bits of the output value of the binary counter 112. While the Q-side control signal selecting circuit 122, which is not selected, outputs a fixed value.

Moreover, in a state C, an amplitude control signal output by the I-side control signal selecting circuit 121 is a limit value on a −side, which is a fixed value, and an amplitude control signal output by the Q-side control signal selecting circuit 122 is an amplitude control signal that inverts the amplitude determined by the lower 2 bits of the output value of the binary counter 112.

In other words, in the state C, the Q-side control signal selecting circuit 122 is selected, and the Q-side control signal selecting circuit 122 outputs the amplitude control signal that is based on the lower 2 bits of the output value of the binary counter 112. While the I-side control signal selecting circuit 121, which is not selected, outputs a fixed value.

In a state D, an amplitude control signal output by the I-side control signal selecting circuit 121 is an amplitude control signal that is determined by the lower 2 bits of the output value of the binary counter 112, and an amplitude control signal output by the Q-side control signal selecting circuit 122 is the limit value on the −side, which is a fixed value.

In other words, in the sate D, the I-side control signal selecting circuit 121 is selected, and the I-side control signal selecting circuit 121 outputs the amplitude control signal that is based on the lower 2 bits of the output value of the binary counter 112. While the Q-side control signal selecting circuit 122, which is not selected, outputs a fixed value.

In this way, the I-side control signal selecting circuit 121 and the Q-side control signal selecting circuit 122 output, according to the upper 2 bits of the output value output by the binary counter 112, either the amplitude control signal that is determined by the lower 2 bits of the output value or the amplitude control signal of a fixed value.

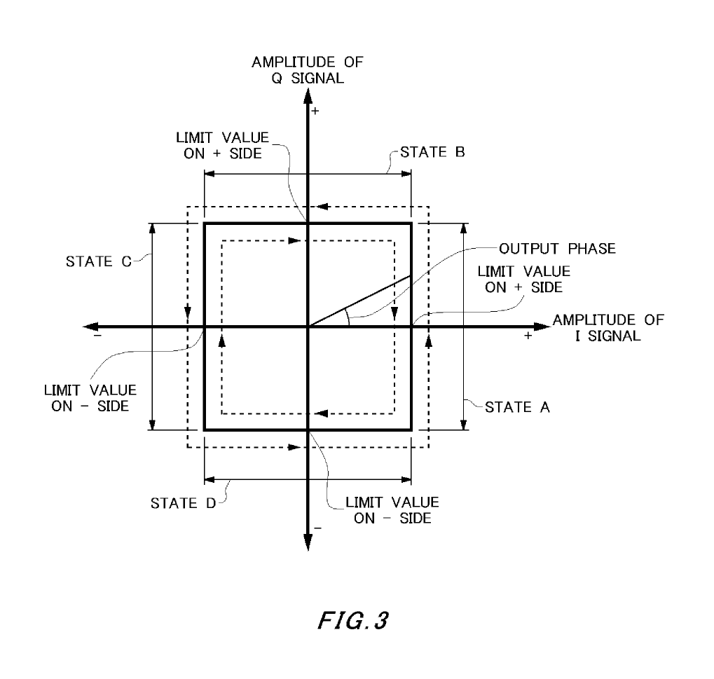

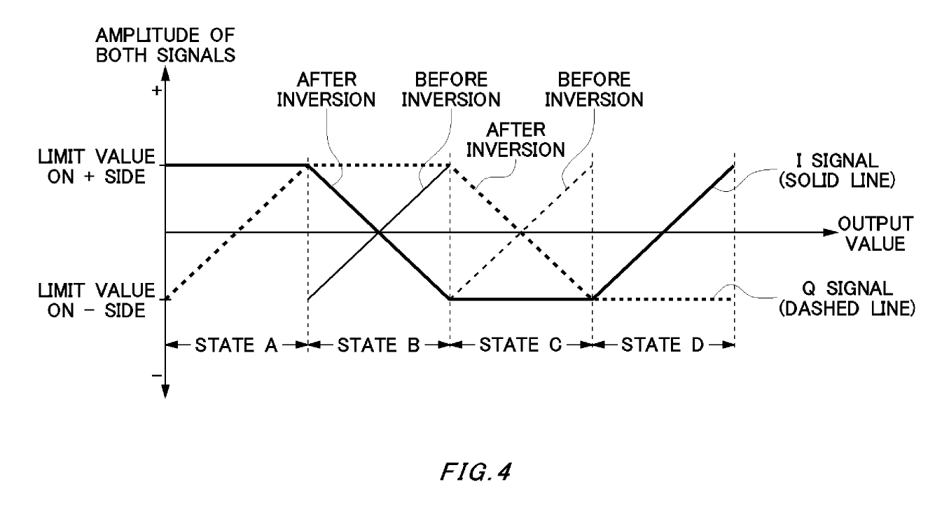

FIG. 3 illustrates an example of trajectories drawn by an amplitude control signal (an I signal) output by the I-side control signal selecting circuit 121 and an amplitude control signal (a Q signal) output by the Q-side control signal selecting circuit 122, where these signals are orthogonal to each other. FIG. 4 illustrates an exemplary relation between the output value and trajectories of the amplitudes of the I signal and the Q signal which are orthogonal to each other. In FIG. 4, the vertical axis shows the amplitudes of the I signal and the Q signal, and the horizontal axis shows the output value of the binary counter 112. In FIG. 4, the I signal is represented by a bold solid line and the Q signal is represented by a bold dashed line.

The reason why the I signal is orthogonal to the Q signal is that the I signal is multiplied by the reference clock by the first multiplier in the IQ modulator 131 whereas the Q signal is multiplied by the reference clock of which phase is shifted by 90° by the second multiplier in the IQ modulator.

Referring to the table shown in FIG. 2, in the state A, an amplitude of the I signal is the limit value on the +side and an amplitude of the Q signal is an amplitude that varies from the limit value on the −side to the limit value on the +side. Here, the amplitude of the Q signal is decided by the lower 2 bits. As can be seen from FIG. 4, the amplitude of the Q signal increases from the limit value on the −side to the limit value on the +side in accordance with the output value.

Referring to the table shown in FIG. 2, in the state B, an amplitude of the I signal is an amplitude that varies from the limit value on the +side to the limit value on the −side, and an amplitude of the Q signal is the limit value on the +side. Here, the amplitude of the I signal is an amplitude generated by inverting the amplitude determined by the lower 2 bits symmetrically with respect to 0.

Referring again to FIG. 4, the I signal before being inverted increases from the limit value on the −side to the limit value on the +side in accordance with the output value. However, since it is inverted symmetrically with respect to 0, the actual amplitude of the I signal decreases from the limit value on the +side to the limit value on the −side in accordance with the output value. The I signal before the inversion is represented by a thin solid line in FIG. 4.

Referring to the table shown in FIG. 2, in the state C, an amplitude of the I signal is the limit value on the −side and an amplitude of the Q signal is an amplitude that varies from the limit value on the +side to the limit value on the −side. Here, the amplitude of the Q signal is generated by inverting the amplitude that is determined by the lower 2 bits symmetrically with respect to 0.

Referring to FIG. 4, the Q signal before the inversion increases from the limit value on the −side to the limit value on the +side in accordance with the output value. However, since it is inverted symmetrically with respect to 0, the actual amplitude of the Q signal decreases from the limit value on the +side to the limit value on the −side in accordance with the output value. The Q signal before the inversion is represented by a thin dashed line in FIG. 4.

Referring to the table shown in FIG. 2, in the state D, an amplitude of the I signal is an amplitude that varies from the limit value on the +side to the limit value on the −side, and an amplitude of the Q signal is the limit value on the −side. Here, the amplitude of the I signal is determined by the lower 2 bits. Referring again to FIG. 4, the I signal before being inverted increases from the limit value on the −side to the limit value on the +side in accordance with the output value.

An angle determined by the I signal and the Q signal is the angle by which the IQ modulator 131 shifts a signal. This angle is referred to as the output phase.

Next, the I-side control signal selecting circuit 121 and the Q-side control signal selecting circuit 122 will be described in detail. The I-side control signal selecting circuit 121 includes a four-input multiplexer 141 that accepts four inputs, and a D/A converter 142. The Q-side control signal selecting circuit 122 includes a four-input multiplexer 143 that accepts four inputs, and a D/A converter 144.

The four-input multiplexer 141 and the four-input multiplexer 143 are respectively supplied with the lower 2 bits of the output value output by the binary counter 112, inverted bits of the lower 2 bits, a bit value indicating a minimum value and a bit value indicating a maximum value. Here, the bit value indicating the minimum value is “00” and the bit value indicating the maximum value is “11”. The four-input multiplexers 141 and 143 select and output one of the above-stated four values depending on the state indicated by the upper 2 bits of the output value of the binary counter 112.

The D/A converter 142 and the D/A converter 144 respectively convert the supplied values to amplitude control signals depending on the value output by the four-input multiplexers 141 and 143. The D/A converter 142 outputs the converted amplitude control signal to the I input of the IQ modulator. The D/A converter 144 outputs the converted amplitude control signal to the Q input of the IQ modulator.

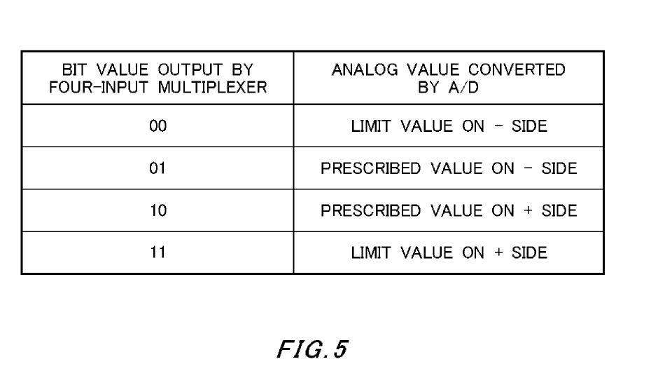

FIG. 5 illustrates an example of relations between bit values output by the four-input multiplexers 141 and 143 and analog values output by the D/A converters 142 and 144 based on the output bit values by the multiplexers. Analog values generated by converting the bit values by the D/A converters become the amplitude control signals.

Referring to FIG. 5, when the bit values output by the four-input multiplexers 141 and 143 are “00,” the D/A converters 142 and 144 convert the bit value to the limit value on the −side. When the bit values output by the four-input multiplexers 141 and 143 are “01,” the D/A converters 142 and 144 convert the bit value to a prescribed value on the −side. When the bit values output by the four-input multiplexers 141 and 143 are “10,” the D/A converters 142 and 144 convert the bit value to a prescribed value on the +side. When the bit values output by the four-input multiplexers 141 and 143 are “11,” the D/A converters 142 and 144 convert the bit value to the limit value on the +side.

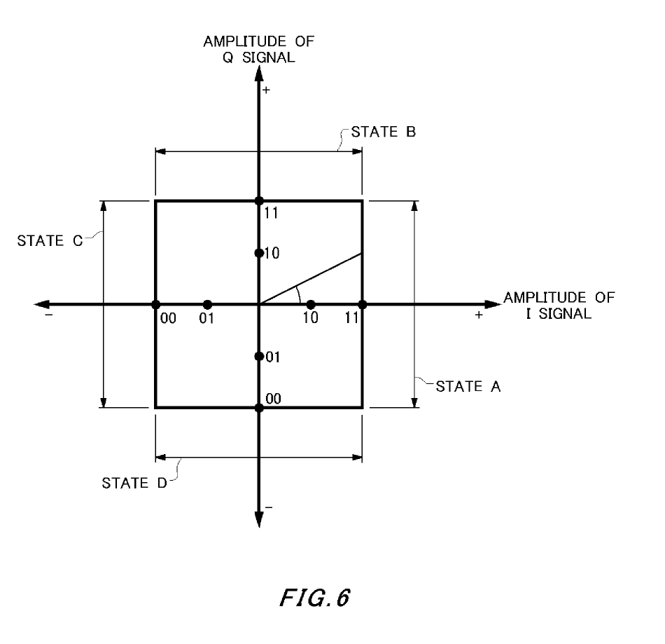

FIG. 6 illustrates amplitudes that correspond to the bit values output by the four-input multiplexers as the trajectories of the I signal and the Q signal that are orthogonal to each other and illustrated in FIG. 3. Referring to FIG. 6, the bit value “00” output by the four-input multiplexers 141 and 143 corresponds to the amplitude of the limit value on the −side. In the same manner, the bit value “01” output by the four-input multiplexers 141 and 143 corresponds to the amplitude of the prescribed value on the −side. The bit value “10” output by the four-input multiplexers 141 and 143 corresponds to the amplitude of the prescribed value on the +side. The bit value “11” output by the four-input multiplexers 141 and 143 corresponds to the amplitude of the limit value on the +side. In this way, the amplitude varies depending on the bit value output by the four-input multiplexers 141 and 143.

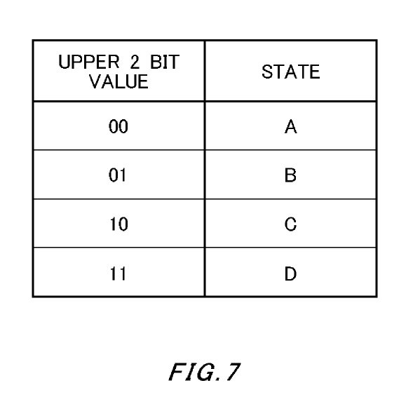

FIG. 7 illustrates relations between states and the upper 2 bits of the output value output by the binary counter 112. When the upper 2 bits of the output value is “00,” the four-input multiplexers 141 and 143 are set to a state A. When the upper 2 bits of the output value is “01,” the four-input multiplexers 141 and 143 are set to a state B. When the upper 2 bits of the output value is “10,” the four-input multiplexers 141 and 143 are set to a state C. When the upper 2 bits of the output value is “11,” the four-input multiplexers 141 and 143 are set to a state D. In accordance with the state, the four-input multiplexers 141 and 143 select and output one of the four values input thereto.

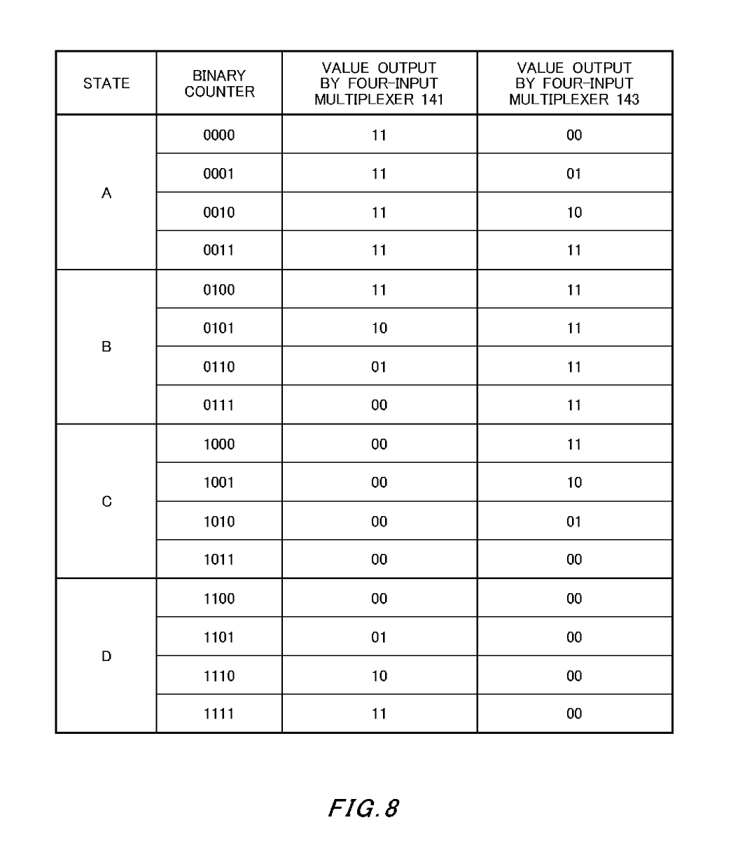

FIG. 8 illustrates an example of relations among the state and the output values output by the four-input multiplexers 141 and 143, depending on the output value output by the binary counter 112.

When the output value of the binary counter 112 is “0000,” “0001,” “0010” or “0011,” the four-input multiplexers 141 and 143 are set to the state A since the upper 2 bits of the output value is “00”. In the state A, the four-input multiplexer 141 selects the bit value indicating the maximum value, which is “11,” from the four values input thereto. At the same time, the four-input multiplexer 143 selects and outputs the lower 2 bits of the output value among the four values input thereto.

When the output value of the binary counter 112 is “0100,” “0101,” “0110” or “0111,” the four-input multiplexers 141 and 143 are set to the state B since the upper 2 bits of the output value is “01”. In the state B, the four-input multiplexer 141 selects the inverted bits of the lower 2 bits of the output value from the four values input thereto, and outputs the selected one. At the same time, the four-input multiplexer 143 selects and outputs the bit value indicating the maximum value, which is “11,” from the four values input thereto.

When the output value of the binary counter 112 is “1000,” “1001,” “1010” or “1011,” the four-input multiplexers 141 and 143 are set to the state C since the upper 2 bits of the output value is “10”. In the state C, the four-input multiplexer 141 selects the bit value indicating the minimum value, which is “00,” from the four values input thereto, and outputs the selected one. At the same time, the four-input multiplexer 143 selects the inverted bits of the lower 2 bits of the output value from the four values input thereto, and outputs the selected one.

When the output value of the binary counter 112 is “1100,” “1101,” “1110” or “1111,” the four-input multiplexers 141 and 143 are set to the state D since the upper 2 bits of the output value is “11”. In the state D, the four-input multiplexer 141 selects the lower 2 bits of the output value from the four values input thereto, and outputs the selected one. At the same time, the four-input multiplexer 143 selects the bit value indicating the minimum value, which is “00,” from the four values input thereto, and outputs the selected one.

In this way, the values output by the four-input multiplexer 141 and the four-input multiplexer 143 are converted by the D/A converter 142 and the D/A converter 144 respectively, and then the amplitude control signals as shown in FIG. 2 and FIG. 3 are supplied respectively to the I input and the Q input of the IQ modulator 131.

As described above, a phase delay at the IQ modulator 131 falls in a range of several dozen of ps. Moreover, the IQ modulator 131 is used for clock recovery instead of a PLL and thereby it is possible to reduce the loop latency. Moreover, by adopting the IQ modulator 131, a low-pass filter with a cut-off frequency of more than several GHz can be used. Consequently, the phase delay minimizes to several dozen of ps, and thereby it is possible to reduce the loop latency.

In addition, by reducing the loop latency it is possible to increase the timing margin at the data acquiring section 104, and thereby it is possible to arrest the degradation in the jitter tolerance. Moreover, it is possible to make the tracking range infinite by using the IQ modulator 131. In this way, it is possible to improve the testing performance of the test apparatus.

Moreover, the size of the circuit as a whole can be reduced since only one binary counter 112 is provided. Furthermore, a circuit for generating an amplitude control signal that is supplied to the IQ modulator 131 based on a phase difference signal output by the phase comparator 111 can be formed from a single binary counter 112 and two multiplexers, so that it is possible to reduce the size of the circuit.

The above described embodiment can be modified to the flowing configurations hereunder described.

(1) The reference clock generated by one reference clock source 101 is supplied to the IQ modulator 131, and the operation of the DUT 150 is controlled by using the reference clock in the above-described embodiment. However, in addition to the clock source that generates the reference clock supplied to the IQ modulator 131, another reference clock source that separately generates a reference clock for controlling the operation of the DUT 150 may be provided.

(2) In the above modification example (1), a frequency of the reference clock supplied to the IQ modulator 131 may not be same as the frequency of the reference clock for controlling the operation of the DUT 150. Alternatively, the frequency of the reference clock supplied to the IQ modulator 131 may be approximately the same as the frequency of the reference clock for controlling the operation of the DUT 150.

(3) The phase shifter in the IQ modulator 131 may shift a signal by any prescribed angle other than 90°. Alternatively, the phase shifter may shift a signal by approximately 90°.

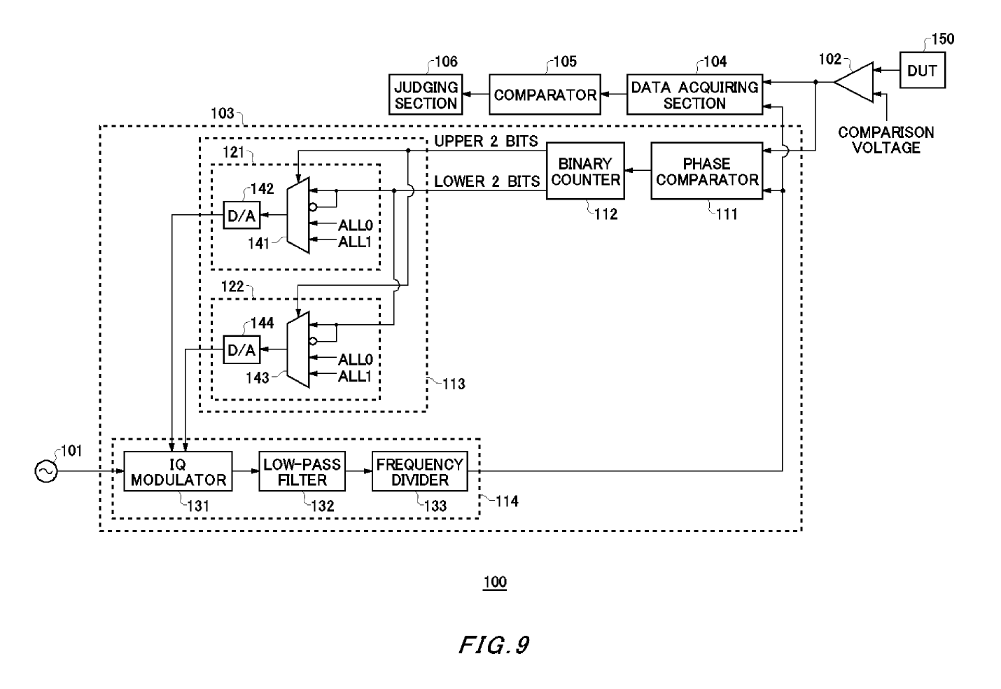

(4) A frequency divider may be provided after the low-pass filter 132. FIG. 9 is a block diagram of the test apparatus 100 in which a frequency divider is provided in the phase shifter 114. In this case, a signal output by a frequency divider 133 is referred to as a recovered clock. The frequency divider 133 outputs the recovered clock to the data acquiring section 104 and the phase comparator 111.

Alternatively, the frequency divider 133 may be provided outside the recovered clock generating circuit 103. In this case, the recovered clock generating circuit 103 outputs the recovered clock to the phase comparator 111 and the frequency divider 133. The frequency divider 133 then supplies the divided recovered clock to the data acquiring section 104.

In this way, it is possible to make the frequency of the reference clock supplied to the phase shifter 114 differ from the frequency of the reference clock for controlling the operation of the DUT 150 according to the frequency division by the frequency divider 133. For example, when a frequency is made 1/N times a frequency by the frequency divider 133, the frequency of the reference clock for controlling the operation of the DUT can be made to 1/N times the frequency of the reference clock supplied to the IQ modulator 131, where N may be a positive integer.

(5) Although the binary counter described above is the four-bit binary counter 112, other n-bit binary counters such as two-bit binary counters and five-bit binary counters can be used, where “n” is a positive integer. Although the multiplexers described above are the four-input multiplexers 141 and 143, any multiplexers having m inputs such as three-input multiplexers and five-input multiplexers can be used, where “m” is a positive integer. The states of the multiplexer are changed according to the upper 2 bits of the value of the binary counter in the above description. Alternatively, the states may be changed according to the upper 1 bit or the upper 3 bits of the value.

While the embodiment of the present invention has been described, the technical scope of the invention is not limited to the above described embodiment. It is apparent to persons skilled in the art that various alterations and improvements can be added to the above-described embodiment. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that tests a device under test, comprising:
a reference clock source that generates a reference clock for controlling operations of the device under test;
a recovered clock generating circuit that generates a recovered clock having approximately the same phase as a phase of output data output by the device under test;
a data acquiring section that acquires an output value of the output data at a timing indicated by a strobe signal that is based on the recovered clock;
a comparator that compares the output value acquired by the data acquiring section to a prescribed expected value; and
a judging section that judges pass or fail of the device under test based on a comparison result made by the comparator;
wherein the recovered clock generating circuit shifts a phase of the reference clock based on a result of comparison between the phase of the output data output by the device under test and a phase of the recovered clock.

2. The test apparatus according to claim 1, wherein the recovered clock generating circuit includes:
a phase comparator that compares the phase of the output data output by the device under test to the phase of the recovered clock, and that outputs a phase difference signal;
a binary counter that increments or decrements an output value based on the phase difference signal;
a control signal generating section that generates a control signal based on the output value of the binary counter; and
a phase shifter that shifts the phase of the reference clock based on the control signal.

3. The test apparatus according to claim 2, wherein
the phase shifter is an IQ modulator that has an I input and a Q input,
the control signal generating section includes an I-side control signal selecting circuit that supplies an amplitude control signal to the I input and a Q-side control signal selecting circuit that supplies an amplitude control signal to the Q input,
one of the I-side control signal selecting circuit and the Q-side control signal selecting circuit is selected in accordance with an upper bit of the output value of the binary counter,
an amplitude control signal based on a lower bit of the output value of the binary counter is output by the selected one of the I-side control signal selecting circuit and the Q-side control signal selecting circuit, and
a fixed value is output by the other of the I-side control signal selecting circuit and the Q-side control signal selecting circuit.

4. The test apparatus according to claim 3, wherein
the I-side control signal selecting circuit and the Q-side control signal selecting circuit are multiplexers that select one of multiple inputs based on an upper bit of the binary counter, and
a bit sequence that includes a lower bit of the binary counter, an inverted bit of the lower bit, a bit indicating a maximum value and a bit indicating a minimum value is input to the multiplexers.

5. The test apparatus according to claim 3, wherein
the phase shifter further includes:
a low-pass filter that removes a high-frequency wave included in an output of the IQ modulator.

6. The test apparatus according to claim 3, wherein
the phase shifter further includes:
a frequency divider that divides a frequency of an output from the IQ modulator.

7. The test apparatus according to claim 3, further comprising:
a frequency divider that divides a frequency of the recovered clock output by the recovered clock generating circuit,
wherein the data acquiring section acquires the output value of the output data at a timing indicated by a strobe signal that is based on the recovered clock of which frequency is divided by the frequency divider.

8. A test method for testing a device under test, comprising:
generating a reference clock for controlling operations of the device under test;
generating a recovered clock that has approximately a same phase as a phase of output data output by the device under test;
acquiring an output value of the output data at a timing indicated by a strobe signal that is based on the recovered clock;
comparing the acquired output value to a prescribed expected value; and
judging pass or fail of the device under test based on a comparison result made in the comparing,
wherein the generating the recovered clock includes:
comparing the phase of the output data output by the device under test to the phase of the recovered clock to output a phase difference signal;
incrementing or decrementing an output value of a binary counter based on the phase difference signal;
generating a control signal based on the output value of the binary counter; and
shifting the phase of the reference clock based on the control signal.

9. The test method according to claim 8, wherein
the shifting the phase is conducted by IQ modulation that has an I input and a Q input,
the generating the control signal includes selecting an I-side control signal to supply an amplitude control signal to the I input and selecting a Q-side control signal to supply an amplitude control signal to the Q input,
one of the selecting the I-side control signal and the selecting the Q-side control signal is selected in accordance with an upper bit of the output value of the binary counter,
an amplitude control signal based on a lower bit of the output value of the binary counter is output in the selected one of the selecting the I-side control signal and the selecting the Q-side control signal, and
a fixed value is output in the other of the selecting the I-side control signal and the selecting the Q-side control signal.

10. The test method according to claim 9, wherein
the selecting the I-side control signal and the selecting the Q-side control signal are multiplexing in which one of multiple inputs is selected based on an upper bit of the binary counter, and
a bit sequence that includes a lower bit of the binary counter, an inverted bit of the lower bit, a bit indicating a maximum value and a bit indicating a minimum value is input in the multiplexing.

11. The test method according to claim 9, wherein the shifting the phase further includes:
low-pass filtering an output of the IQ modulation to remove a high-frequency wave included therein.

12. The test method according to claim 9, wherein the shifting the phase further includes:
dividing a frequency of an output of the IQ modulation.

13. The test method according to claim 9, further comprising:
dividing a frequency of the generated recovered clock,
wherein in the acquiring the output value of the output data, the output value of the output data is acquired at a timing indicated by a strobe signal that is based on the recovered clock of which frequency is divided in the dividing.
